(19) United States
(12) Patent Application Publication
(10) Pub. No.: US 2020/0280134 A1
(43) Pub. Date: Sep. 3, 2020

(54) HIGHLY INTEGRATED SMART MICROWAVE DIGITAL RADIO ARCHITECTURE

(71) Applicant: ZTE CORPORATION, Shenzhen (CN)

(72) Inventors: Ying SHEN, Chapel Hill, NC (US); Ed John NEALIS, Cary, NC (US); Zhiping Feng, Chapel Hill, NC (US); Thanh NGUYEN, Cary, NC (US); Shawn WALSH, Cary, NC (US); Aleksandr SEMENYSHEV, Apex, NC (US); Andrey KOCHETKOV, Cary, NC (US)

(21) Appl. No.: 16/068,066

(22) PCT Filed: Jan. 3, 2017
(86) PCT No.: PCT/US2017/012052

§ 371 Date: Jul. 3, 2018

Related U.S. Application Data
(60) Provisional application No. 62/274,721, filed on Jan. 4, 2016.
(60) Provisional application No. 62/274,725, filed on Jan. 4, 2016.

(51) Int. Cl. H01Q 13/08; H01Q 13/20; H01Q 21/28; H04B 1/00; H04B 1/48; H03F 3/24

(52) U.S. Cl. CPC H01Q 13/08; H01Q 13/206; H01Q 21/28; H03F 2200/451; H04B 1/48; H03F 3/24; H04B 1/0057

(57) ABSTRACT

An outdoor microwave radio, which supports two channels aggregation, includes a cable interface, a radio frequency processing section, and an antenna coupling section. The cable interface includes two cables, each cable configured to receive an analog intermediate frequency signal from a modem output at a remote indoor microwave radio. The radio frequency processing section configured to process the two analog intermediate frequency signals into one analog radio frequency signal. The antenna coupling section includes a co-plane circulator for connecting to an antenna and transmitting the analog radio frequency signal using the antenna.

### TECHNICAL FIELD

The present application generally relates to devices for wireless communications, and more particularly, to highly integrated smart microwave digital radio architecture.

### BACKGROUND

4G Long Term Evolution (LTE) mobile networks are becoming a reality. The backhaul point to point microwave radios is a key part of this 4G network and plays an important role to a successful LTE network. Traditional indoor/outdoor hybrid microwave digital radios still own the majority of the mobile backhaul market. With more and more 4G base station installation, there is a growing requirement for a radio with higher performance, smaller size, and lower cost.

### SUMMARY

To catch up with the rapid growing 4G rollout, the microwave backhaul point to point digital radio has continuous increasing requirements on higher performance, such as to support 2048 QAM and 4096 QAM, to support adaptive pre-distortion without extra bandwidth requirement, lengthy calibration, and correction mechanism, and to have higher integration, more flexible configurations, and smaller size with lower cost.

According to some embodiments of the present application, an outdoor microwave radio that supports two channels aggregation, comprises a cable interface; a radio frequency processing section; and an antenna coupling section. The cable interface includes two cables, each cable configured to receive an analog intermediate frequency signal from a modem output at a remote indoor microwave radio. The radio frequency processing section configured to process the two analog intermediate frequency signals into one analog radio frequency signal. The antenna coupling section includes a co-plane circulator for connecting to an antenna and transmitting the analog radio frequency signal using the antenna.

According to some embodiments of the present application, an integrated outdoor radio frequency unit includes a housing including two N-type connectors and an antenna port; a transmitter-receiver board located within the housing for communicating with an indoor radio unit via the two N-type connectors; a transmitter isolator and a receiver isolator, each coupled to a respective terminal of the transmitter-receiver board; a transmitter E-plane insert coupled to the transmitter isolator via a first microstrip line to E-plane waveguide transition; a receiver E-plane insert coupled to the receiver isolator via a second microstrip line to E-plane waveguide transition; a circulator coupled to the transmitter E-plane filter via a third E-plane waveguide to microstrip transition, the receiver E-plane filter via a fourth E-plane waveguide to microstrip transition, and the antenna port via a microstrip to H-plane waveguide transition. The transmitter isolator, the receiver isolator, the transmitter E-plane insert, the receiver E-plane insert, and the circulator are co-plane.

### BRIEF DESCRIPTION OF DRAWINGS

The accompanying drawings, which are included to provide a further understanding of the embodiments and are incorporated herein and constitute a part of the specification, illustrate the described embodiments and together with the description serve to explain the underlying principles. Like reference numerals refer to corresponding parts.

FIG. 1 is a block diagram depicting a traditional indoor/outdoor split radio architecture.

FIG. 2 is a block diagram depicting an N-split radio architecture.

FIG. 3 is a block diagram depicting one outdoor radio unit (ODU) supporting two channels aggregation in one radio frequency (RF) chain according to some embodiments of the present application.

FIG. 4 is a block diagram depicting an N-split radio architecture using multiple ODUs, each supporting two channels aggregation, according to some embodiments of the present application.

FIG. 5 is a block diagram depicting internal structure of a radio frequency unit (RFU) aggregation according to some embodiments of the present application.

FIG. 6 is a block diagram depicting a proposed RFU according to some embodiments of the present application.

FIG. 7 is a block diagram depicting a microstrip line isolator/circulator according to some embodiments of the present application.

FIG. 8 depicts an E-plane filter according to some embodiments of the present application.

FIG. 9 depicts a microstrip line to E-plane waveguide transition according to some embodiments of the present application.

FIG. 10 depicts a microstrip line to H-plane waveguide transition according to some embodiments of the present application.

FIG. 11 depicts a function and mechanical layout of a highly integrated RFU according to some embodiments of the present application.

FIGS. 12A and 12B depict a highly integrated low cost RFU, (a) the exploded view, (b) the side view of a partially assembled RFU cut at the center according to some embodiments of the present application.

FIG. 13 depicts a tunable filter tuning mechanism, (a) layout of a tunable E-plane filter, (b) Simulation results of a tunable E-plane filter according to some embodiments of the present application.

FIG. 14 depicts an exploded view of the tuning filter integrated with RFU to show mechanical mechanism of the control of the tuning plate according to some embodiments of the present application.

FIG. 15 depicts an integrated compact tunable radio unit according to some embodiments of the present application.

### DETAILED DESCRIPTION

Reference will now be made in detail to embodiments, examples of which are illustrated in the accompanying drawings. In the following detailed description, numerous non-limiting specific details are set forth in order to assist in understanding the subject matter presented herein. It will be apparent, however, to one of ordinary skill in the art that various alternatives may be used without departing from the scope of claims and the subject matter may be practiced without these specific details. For example, it will be apparent to one of ordinary skill in the art that the subject matter presented herein can be implemented on many types of radio communication systems.

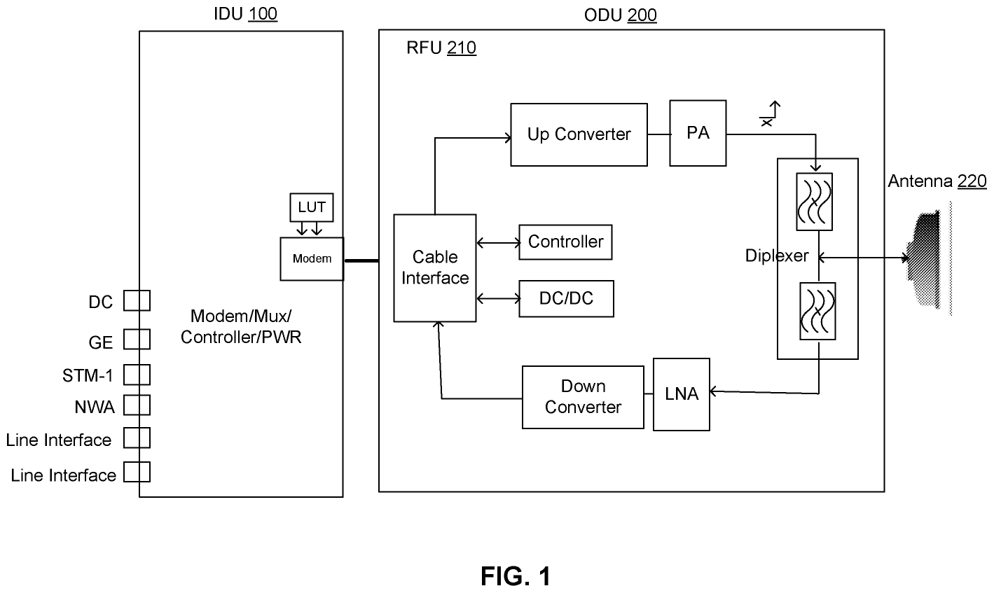

FIG. 1 shows a traditional indoor/outdoor split radio block diagram, consisting of one indoor unit (IDU) 100 and one outdoor unit (ODU) 200. IDU 100 includes modem, multiplex, controller, power supply, and customer interface circuitries. ODU 200 includes a radio frequency unit 210 (RFU) and an antenna 220. RFU 210 further includes a cable interface, up/down radio frequency converters, a power amplifier (PA), a low-noise amplifier (LNA), filters, gain control, RF signal processing, and a diplexer or antenna coupling unit.

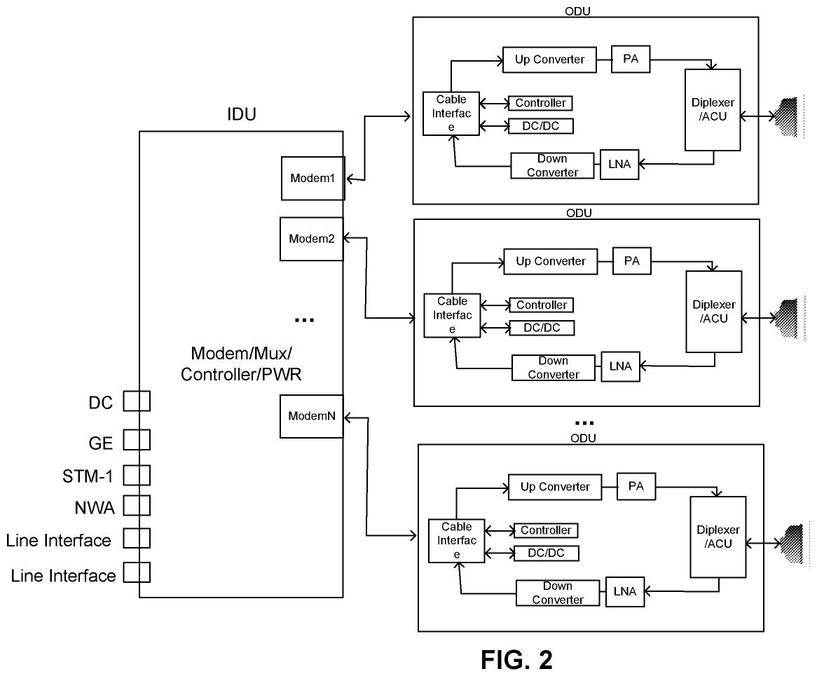

As shown in FIG. 2, to minimize the indoor needed space and reduce the overall hardware cost, an IDU in the market typically shares one power supply module, one controller card, one common customer interface module, and many modem cards (N), each modem card connecting to one ODU, such that this single IDU with multiple N modems supports maximum N ODUs.

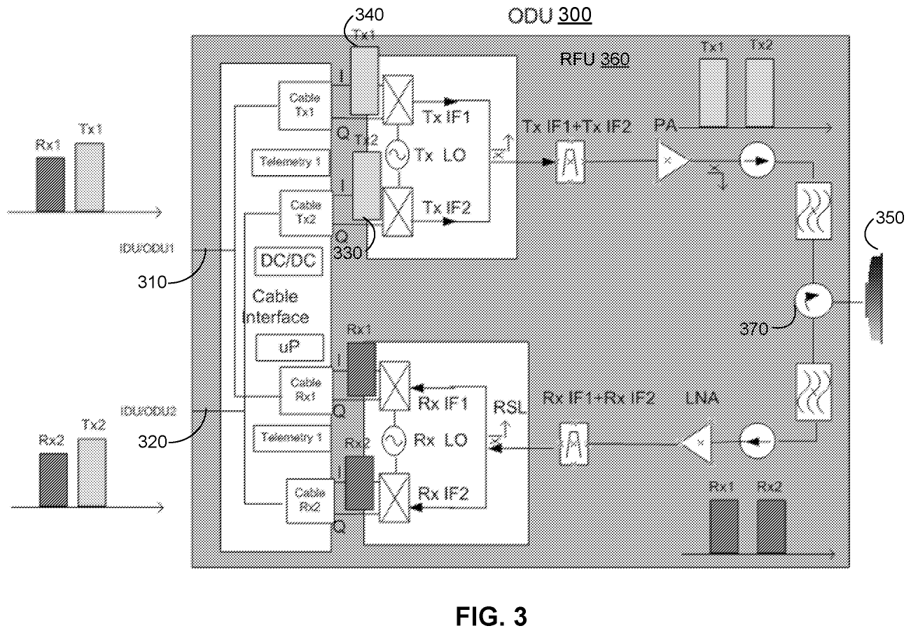

In this application, a new radio architecture design of a single ODU 300 supporting two channels aggregation in one RF chain is depicted in FIG. 3. FIG. 3 shows that there are two cables 310 and 320, which connect the ODU 300 directly to two modem cards in the IDU (not shown in FIG. 3). The two channels from two transmitters 330 and 340 are combined into a common RF chain, then to the antenna output. Similarly, for the receiver side, the antenna 350 receives signals from two channels combined in one RF chain at another ODU (not shown in FIG. 3), which are then split into two baseband Rx signals. Note that two channels can be either side by side or at certain channel spacing.

Note that the ODU 300 without the antenna 350 is often referred as a radio frequency unit 360 (RFU). As shown in the FIG. 3, the RFU 360 includes an integrated circulator 370, which offers a better isolation between transmitter (Tx) and receiver (Rx) and a better return loss at the antenna port and relaxes the rejection requirement for both the Tx and Rx filters.

Compared with the conventional ODU design shown in FIGS. 1 and 2, the ODU having two channels aggregation in one RF chain has the following key advantages:
Reducing the cost and size of the overall system and network by combining two channels into one RFU instead of two RFUs;
Providing additional protection, if one channel input fails, by switching to the other channel immediately;
Providing higher system throughput by combining two channels together, which can either be side by side or at a certain distance; and
Providing better isolation between Tx and Rx and better return loss at the antenna port and relaxing both Tx and Rx filter rejection requirement using an integrated circulator.

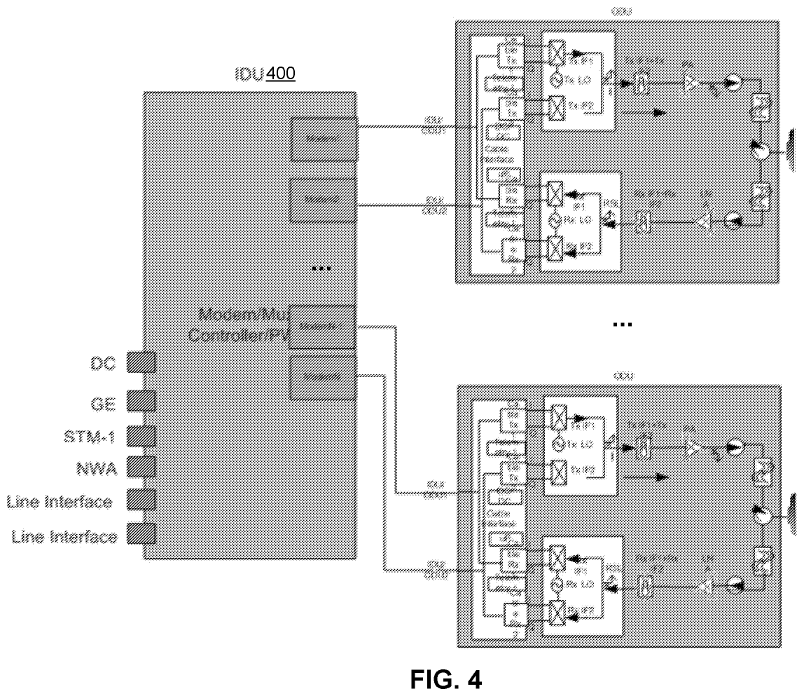

As shown in FIG. 4, an N-split radio architecture only requires half the number of ODUs depicted in FIG. 3 as it does in FIG. 2. Note that each ODU in FIG. 3 have two cables connected to two modem cards in the IDU 400 so as to support two channels aggregation.

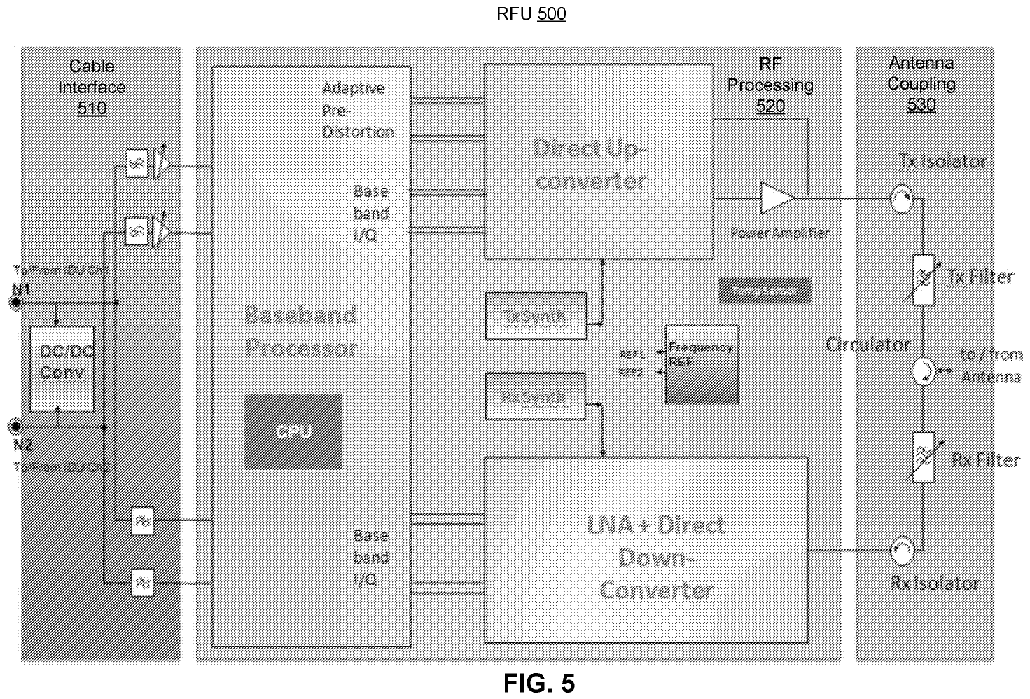

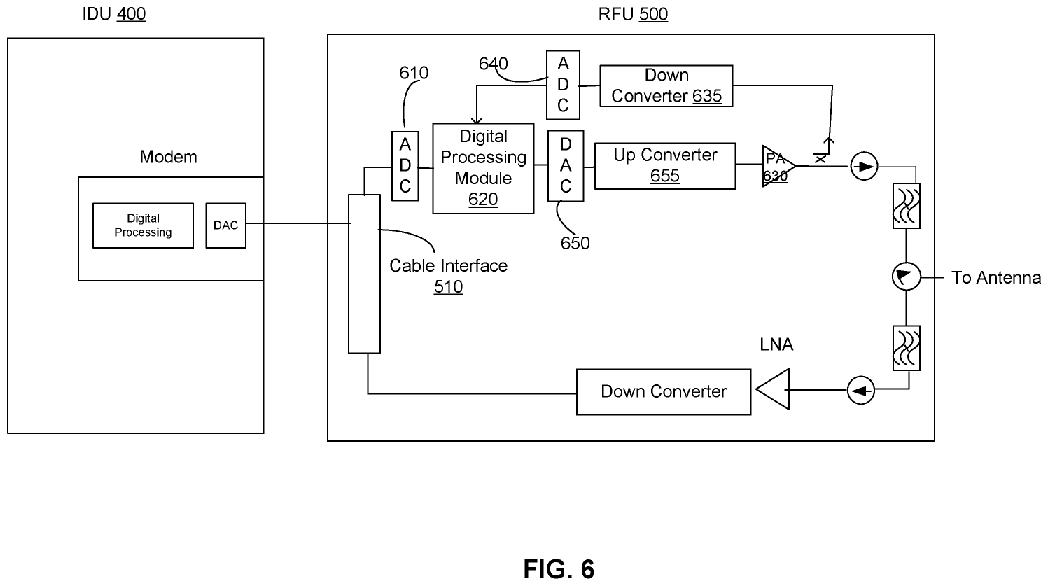

FIG. 5 provides a more detailed block diagram and the function block diagram of a RFU 500, which supports two channels aggregation. The RFU 500 consists of three components: a cable interface 510, an RF processing section 520 and an antenna coupling section 530. As shown in FIG. 5, a close loop adaptive digital pre-distortion (ADPD) is employed in the RFU 500. FIG. 6 shows the simplified single channel version of this RFU block diagram when it has one connection to a modem in the IDU 400.

The cable interface 510 receives the analog Tx intermediate frequency (IF) signal from the IDU modem output (not shown in FIG. 5). Then the analog signal is converted to a digital signal through an analog-digital converter 610 (ADC), which is followed by a digital processing module 620 including a digital pre-distortion. The digital pre-distortion receives a digital feedback signal from the output of the power amplifier 630 (PA), which is down-converted by a down-converter 635 to the baseband IF signal and then digitized through another ADC 640. The digital IF input signal from the IDU 400 and the digital feedback signal from the PA 630 are combined together through the digital processing module 620, transferred back to analog using digital-analog converter 650 (DAC), and then up-converted by an up-converter 655 to an RF signal.

Compared with the conventional approach, the proposed architecture has the following key advantages:
Since both IF and PA feedback signals have been transferred from analog to digital, the digital pre-distortion (DPD) processing is performed in the digital domain and therefore has a higher DPD efficiency;
Since the close loop DPD is done within the RFU 500, three times wider bandwidth, which was required by the conventional approach, is not required for the IDU 400 to the RFU 500 interface, greatly saving the cost and reducing the technical challenge for the cable interface circuitry and spurious requirement; and
With this architecture, the IF signal is transferred back to the digital domain by the ADC 640 and then back to analog domain by the DAC 650, the resulting Tx signal has a better signal to noise ratio (SNR), which makes it easier to meet the overall system mask and spurious requirement.

As shown in FIG. 6, the Tx IF analog signal is transferred from analog domain to digital domain through the ADC 610 and then combined with the digital feedback signal from the PA 630. After the digital signal processing including the adaptive digital pre-distortion, the Tx IF signal is transferred back from digital domain to analog domain through DAC 650. This analog-digital-analog process not only accommodates ADPD within the RFU, but also re-generates Tx IF to have a better SNR, which makes the system easier to achieve the total SNR needed for 4096 QAM modulation. In addition, by eliminating the 3 times of bandwidth requirement, it makes the design of Tx circuits easier to achieve the wideband 112 MHz cable interface circuitry, possible with the common cable interface frequency of 350 MHz for Tx IF frequency and 140 MHz for Rx IF frequency.

Since there is no RF filtering in this PA feedback loop path, the actual ADPD processing bandwidth depends on the DAC capability and the baseband filtering bandwidth, and can therefore handle a wider bandwidth than traditional DPD, which has limited bandwidth due to the RF filtering bandwidth limitation.

In sum, the proposed architecture has the following key advantages:
Support 112 MHz with ADPD through a common traditional 350 MHz/140 MHz cable interface;
Due to a Tx IF Analog-Digital-Analog transition, the system has higher SNR and can meet the 2K and 4K QAM requirement relatively easily compared with a conventional system; and
Since there is no RF filtering in this RF conversion scheme, ADPD can handle wider signal or combined signal bandwidth than a traditional open loop DPD or close loop adaptive analog pre-distortion (AAPD) approaches.

In this RFU architecture, a co-plane Tx isolator, a co-plane Rx isolator and a co-plane circulator are proposed for connecting the antenna to both Tx and Rx filters.

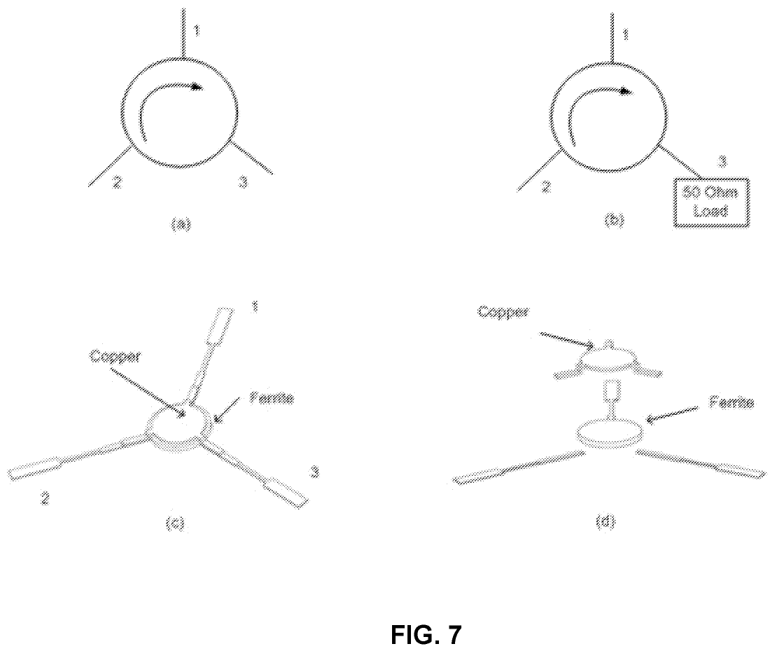

FIG. 7 (a) shows an isolator/circulator. The signal can only follows the arrow direction and transmits from port 2 to port 1, then to port 3. Note that if one port of the circulator connects to a matching load, the signal flowing to the port will be absorbed by the matching load. In this case, the circulator becomes an isolator. Therefore, the circulator can be used as an isolator as long as the third port connecting to a matching load. FIG. 7 (b) shows a diagram of an isolator, signal can only flow from port 2 to port 1. Whatever signal reaching port 3 will be absorbed by the matching load. FIG. 7 (c)/(d) show both exploded and integrated co-plane isolator or circulator structure, in which the input and output of the isolator or circulator connect to the traditional microstrip line.

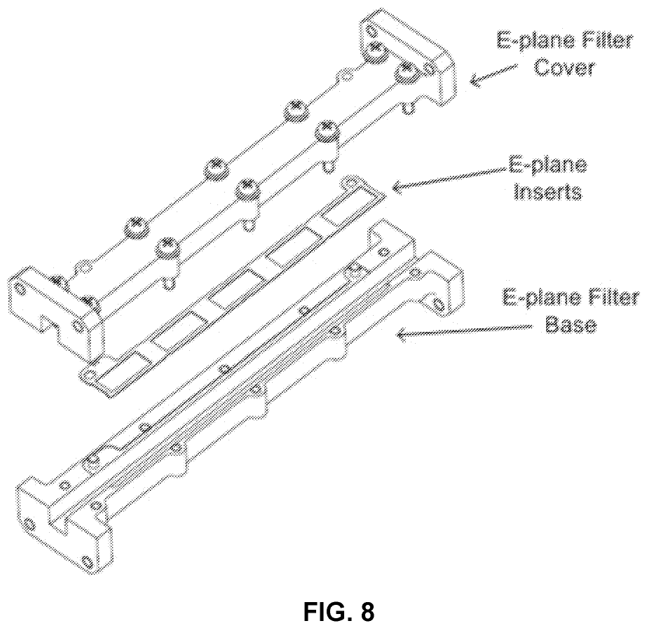

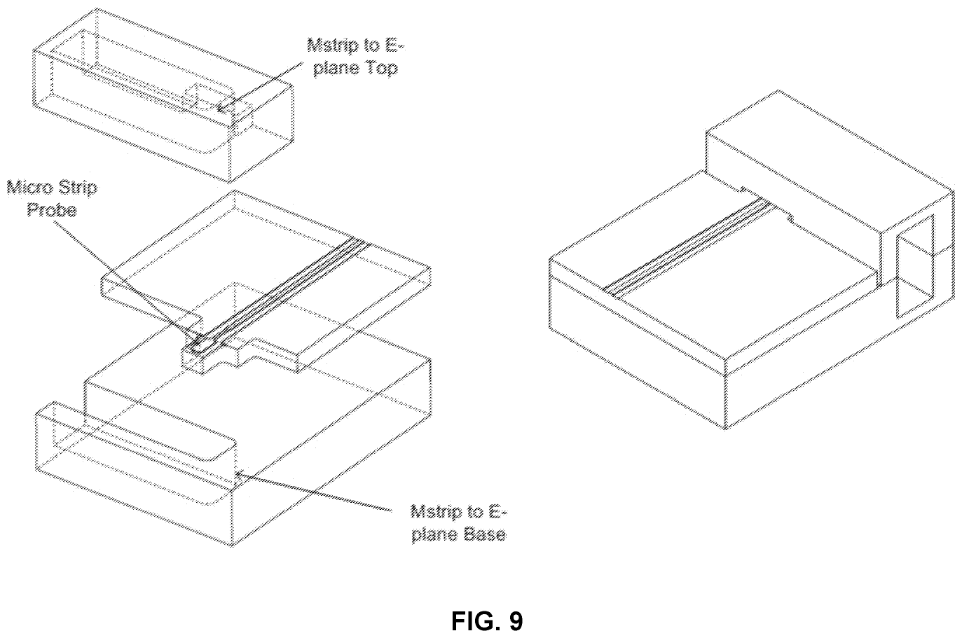

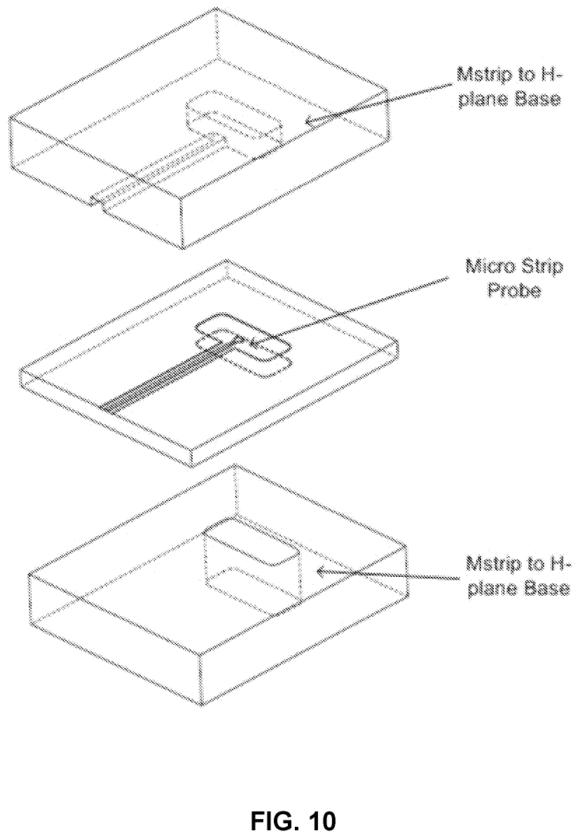

FIG. 8 shows the exploded view of an E-plane filter. FIGS. 9 and 10 show the microstrip line to waveguide (WG) transitions in E-plane and H-plane, respectively.

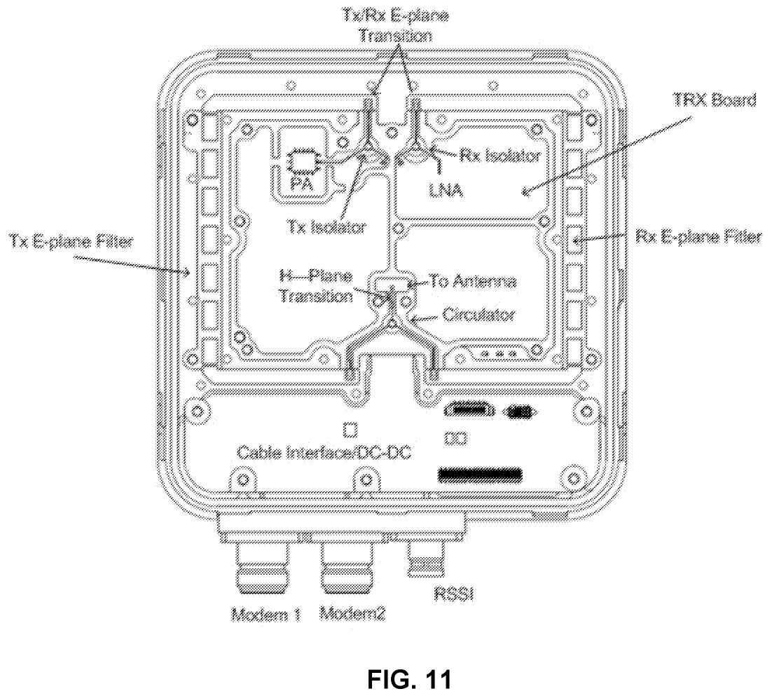

FIG. 11 shows the function and mechanical layout an RFU housing with different parts integrated in one common layer. There are two N-type and one BNC (Bayonet Neill-Concelman) connectors at the bottom of the RFU housing. The two N-type connectors are responsible for connecting to modem 1 and modem 2 of the IDU (not shown in FIG. 11). The BNC connector is used for displaying the receiver signal strength indicator (RSSI). The TRX module is located on the PCB in the RFU housing, which includes a cable interface, a DC/DC converter, digital processing, transmitters (Tx), ADPD, PA, receivers (Rx), Tx/Rx local synthesizers, a common reference and CPU. The output of the PA connects to a co-plane Tx isolator and then to a Tx E-plane filter through a microstrip line to E-plane waveguide transition. The Tx E-plane filter then connects to a co-plane circulator through a E-plane waveguide to microstrip transition, finally to the antenna port through a micro strip to H-plane WG transition. The connection path for the Rx chain is similar.

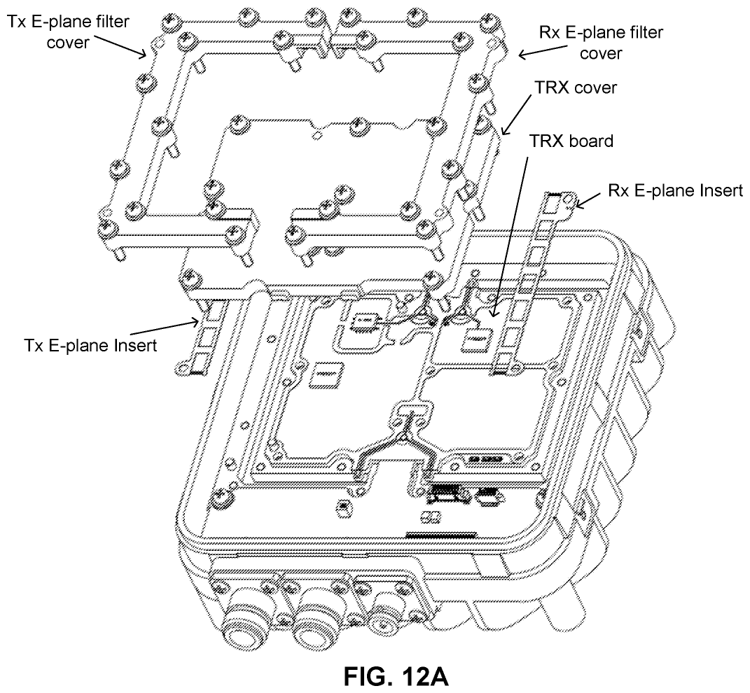

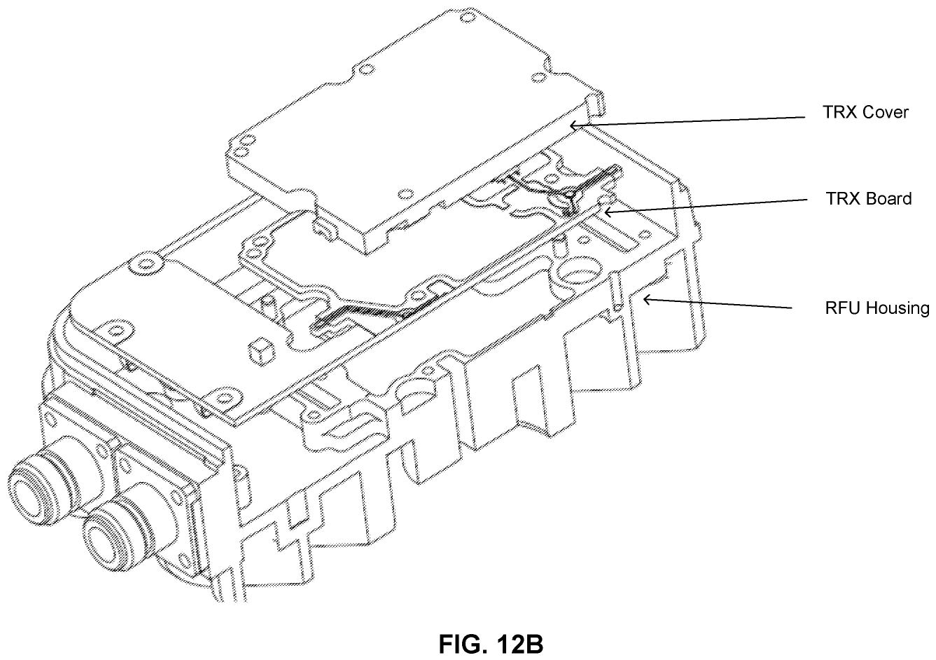

FIGS. 12A and 12B show the exploded and side view of the RFU housing. The RFU housing base is the common base for the TRX module, all the microstrip to waveguide transitions, the antenna output, and the Tx/Rx E-plane filters. The RFU housing also supports thermal dissipation and connects to the right connectors. All the circuitries in the RFU housing are on the same plane and share the common RFU housing as the base to achieve the lowest possible production cost with the smallest possible overall volume while maintain the highest radio performance.

Finally, with the E-plane filters, it is possible to use the common mechanics in the same frequency band to achieve different RFU options due to various Tx/Rx spacing or various frequency bands under the same Tx/Rx spacing by changing only the inserts of the E-plane filter, which reduces the cost further.

Therefore, the proposed architecture has the following key advantages:
All parts in the RFU housing are surface mount parts on the same plane, which minimize the overall RFU volume;
The RFU housing uses co-plane Tx isolator, Rx isolator, and circulator, integrated with microstrip line to waveguide transitions in E-plane and H-plane, and both Tx and Rx E-plane filters to minimize the overall the size, the cost, and the signal loss of RFU;
The RFU housing base is the common base for the TRX module, microstrip line to waveguide transitions in E-plane and H-plane, E-plane filters, and antenna output port;
Easy change E-plane inserts to change the RFU frequency band options due to various T/R spacing and various bands options under the same T/R spacing; and
The whole RFU is integrated and designed together seamlessly.

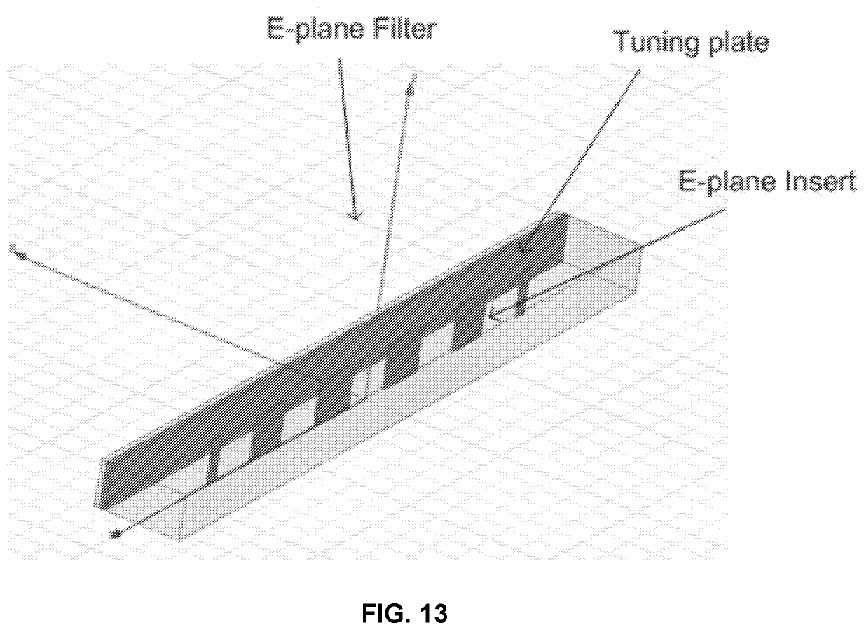

With the introduction of E-plane filter, this RFU architecture also supports the optional tunable filter option. Tunable RFU offers an advantage to a network service provider because of its network flexibility, low maintenance and spare cost and fast network deployment. A network service provider can have the common RFU and then tune to its licensed frequency band per each cell deployment frequency. Also, as the spare parts, a network service provider can spare the common RFU as a general use. Typically, two tunable RFU options can cover each frequency band instead of existing many hardware options per various T/R spacing and many options under the same T/R spacing. FIG. 13 shows a tunable E-plane filter tuning mechanism. An additional dielectric tuning plate is inserted in normal E-plane filter. By moving the tuning plate up and down, the filter response will shift left and right to achieve the filter tuning capability.

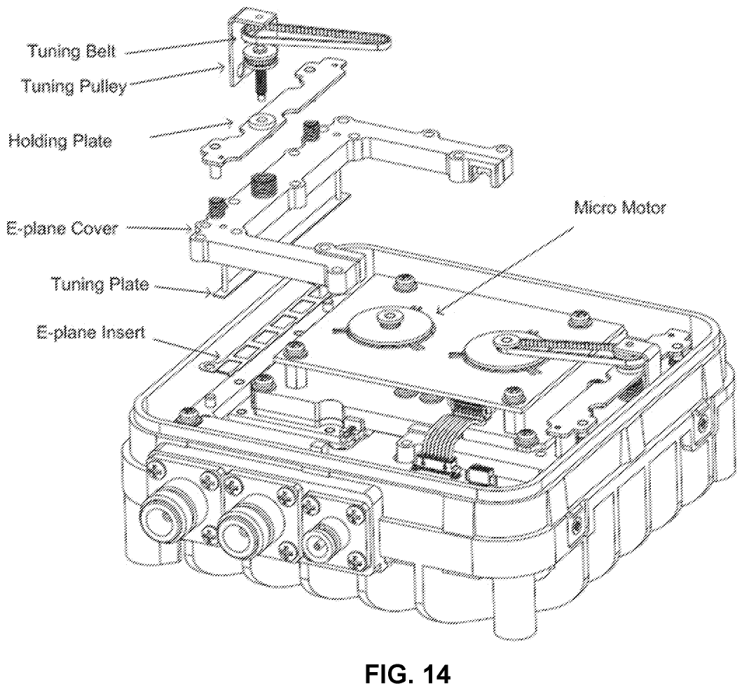

FIG. 14 shows the proposed concept of mechanical mechanism of the tunable E plane filter. It introduces another micro controller board on the top of the TRX module using two very small PCB based micro motors, one for the Tx tunable filter and the other for the Rx tunable filter, to independently control the Tx and Rx E-plane filters. The motor controls the tuning pulley through a tuning belt. Through the holding plate, the pulley moves the tuning plate up and down to achieve the tuning capability. Tuning depth vs. frequency is through pre-calibration, with the correction factor for temperature and frequency.

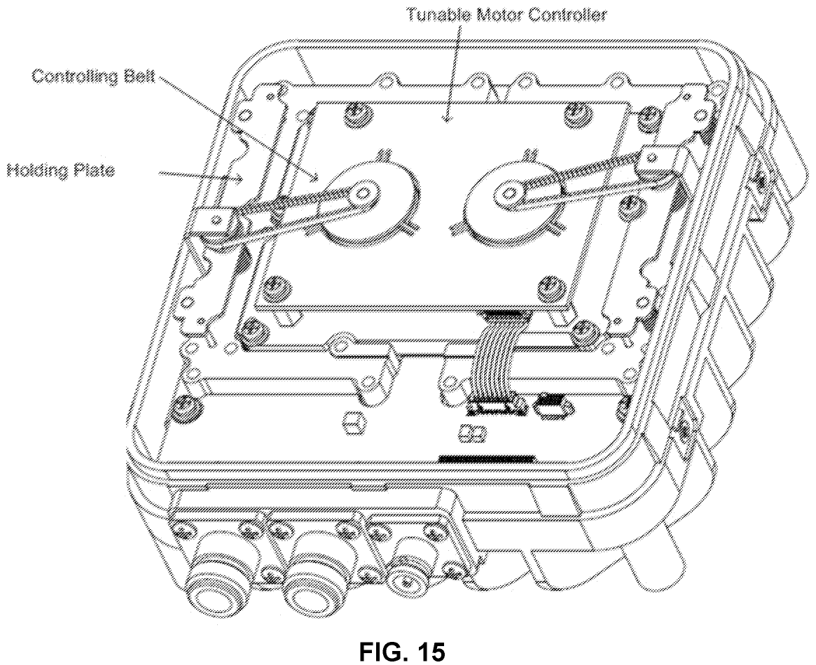

FIG. 15 shows the integrated two layer compact smart microwave digital radio unit with low cost, high performance. First layer integrates all the RFU circuitry and the second layer is the further integration by adding the tuning controller board to achieve the tunable filter function.

The proposed architecture has the following key advantages:
A tunable microwave digital radio uses compact low cost tunable E-plane based structure with proposed micro PCB motors with gear, belt and holding plate mechanism.
This smart RFU support optional both non-tunable and tunable E-plane architecture to meet various both low and high end customer needs.

Various embodiments of the antenna feeder design as discussed in the present disclosure can be used in digital microwave radios, such as 2T2R digital microwave radios. The compact antenna feeder can be designed for different frequency bands. Such design can reduce the overall size of the dual polarization antenna feeder and improves the isolation by introducing additional circulators and isolators into the antenna feeder. Moreover, the manufacturing and assemble cost is also reduced due to a simple manufacturing and assemble process based on the new design.

The terminology used in the description of the embodiments herein is for the purpose of describing particular embodiments only and is not intended to limit the scope of claims. As used in the description of the embodiments and the appended claims, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will also be understood that, although the terms first, second, etc. may be used herein to describe various elements, these elements should not be limited by these terms. These terms are only used to distinguish one element from another. For example, a first port could be termed a second port, and, similarly, a second port could be termed a first port, without departing from the scope of the embodiments. The first port and the second port are both ports, but they are not the same port.

As used herein, the terms “couple,” “coupling,” and “coupled” are used to indicate that multiple components are connected in a way such that a first component of the multiple components is capable of receiving a signal from a second component of the multiple components, unless indicated otherwise. In some cases, two components are indirectly coupled, indicating that one or more components (e.g., filters, waveguides, etc.) are located between the two components but a first component of the two components is capable of receiving signals from a second component of the two components.

Many modifications and alternative embodiments of the embodiments described herein will come to mind to one skilled in the art having the benefit of the teachings presented in the foregoing descriptions and the associated drawings. Therefore, it is to be understood that the scope of claims are not to be limited to the specific examples of the embodiments disclosed and that modifications and other embodiments are intended to be included within the scope of the appended claims. Although specific terms are employed herein, they are used in a generic and descriptive sense only and not for purposes of limitation.

The embodiments were chosen and described in order to best explain the underlying principles and their practical applications, to thereby enable others skilled in the art to best utilize the underlying principles and various embodiments with various modifications as are suited to the particular use contemplated.

What is claimed is:

1. An outdoor microwave radio that supports two channels aggregation, comprising:
a cable interface;
a radio frequency processing section; and
an antenna coupling section, wherein:
the cable interface includes two cables, each cable configured to receive an analog intermediate frequency signal from a modem output at a remote indoor microwave radio;
the radio frequency processing section configured to process the two analog intermediate frequency signals into one analog radio frequency signal; and
the antenna coupling section includes a co-plane circulator for connecting to an antenna and transmitting the analog radio frequency signal using the antenna.

2. The outdoor microwave radio of claim 1, wherein the radio frequency processing section is further configured to down-convert an analog radio frequency signal received from the antenna via the antenna coupling section into an analog intermediate frequency signal and perform low-noise amplification to the analog intermediate frequency signal and split the analog intermediate frequency signal into two analog intermediate frequency signals, each analog intermediate frequency signal being transmitted to a modem input at the remote indoor microwave radio.

3. The outdoor microwave radio of claim 1, wherein the radio frequency processing section further includes:
a first analog-digital converter for converting each of the two analog intermediate frequency signals into a corresponding digital intermediate frequency signal.

4. The outdoor microwave radio of claim 3, wherein the radio frequency processing section further includes:
a digital processing module for combining the two digital intermediate frequency signals into one digital intermediate frequency signal and performing adaptive digital pre-distortion to the combined digital intermediate frequency signal in accordance with a digital feedback signal from a second analog-digital converter.

5. The outdoor microwave radio of claim 4, wherein the radio frequency processing section further includes:
a digital-analog converter for converting the combined digital intermediate frequency signal after the adaptive digital pre-distortion back into an analog intermediate frequency signal.

6. The outdoor microwave radio of claim 5, wherein the radio frequency processing section further includes:
an up-converter for up-converting the analog intermediate frequency signal from the digital-analog converter to an analog radio frequency signal.

7. The outdoor microwave radio of claim 6, wherein the radio frequency processing section further includes:
a power amplifier for amplifying the analog radio frequency signal, which is then provided to the antenna coupling section.

8. The outdoor microwave radio of claim 6, wherein the radio frequency processing section further includes:
a down-converter for down-converting the analog radio frequency signal into an analog intermediate frequency signal, which is converted into the digital feedback signal by the second analog-digital converter.

9. An integrated outdoor radio frequency unit, comprising:
a housing including two N-type connectors and an antenna port;
a transmitter-receiver board located within the housing for communicating with an indoor radio unit via the two N-type connectors;
a transmitter isolator and a receiver isolator, each coupled to a respective terminal of the transmitter-receiver board;
a transmitter E-plane insert coupled to the transmitter isolator via a first microstrip line to E-plane waveguide transition;
a receiver E-plane insert coupled to the receiver isolator via a second microstrip line to E-plane waveguide transition;
a circulator coupled to the transmitter E-plane filter via a third E-plane waveguide to microstrip transition, the receiver E-plane filter via a fourth E-plane waveguide to microstrip transition, and the antenna port via a microstrip to H-plane waveguide transition,
wherein the transmitter isolator, the receiver isolator, the transmitter E-plane insert, the receiver E-plane insert, and the circulator are co-plane.

10. The integrated outdoor radio frequency unit of claim 9, wherein the transmitter-receiver board is configured to process two analog intermediate frequency signals received from the indoor radio unit through the two N-type connectors into an analog radio frequency signal.

11. The integrated outdoor radio frequency unit of claim 9, wherein the housing provides a common base for the transmitter-receiver board, the multiple microstrip to waveguide transitions, the antenna port, the transmitter isolator, the receiver isolator, the transmitter E-plane insert, the receiver E-plane insert, and the circulator.
